(19) United States
(12) Patent Application Publication
(10) Pub. No.: US 2012/0266044 A1
(43) Pub. Date: Oct. 18, 2012

(54) NETWORK-CODING-BASED DISTRIBUTED FILE SYSTEM

(75) Inventors: Yuchong Hu, Wuhan (CN); Chiu-man Yu, Shatin (HK); Yan Kit Li, Fanling (HK); Pak-Ching Patrick Lee, Kwai Chung (HK); Chi-Shing John Lui, Kowloon (HK)

(73) Assignee: The Chinese University of Hong Kong, New Territories (HK)

(21) Appl. No.: 13/431,553

(22) Filed: Mar. 27, 2012

Related U.S. Application Data
(60) Provisional application No. 61/476,561, filed on Apr. 18, 2011.

(51) Int. Cl. H03M 13/05; G06F 11/10; G06F 12/00

(52) U.S. Cl. 714/763; 711/114; 711/E12.001; 714/E11.034

(57) ABSTRACT

A network-coding-based distributed file system (NCFS) is disclosed. The NCFS may include a file system layer, a disk layer, and a coding layer. The file system layer may be configured to receive a request, for an operation on data within a data block, to specify the data block to be accessed in a storage node of a plurality of storage nodes. The disk layer may provide an interface to the file system to provide access the plurality of storage nodes via a network. The coding layer may be connected between the file system layer and the disk layer, to encode and/or decode functions of fault-tolerant storage schemes based on a class of maximum distance separable (MDS) codes. Additional apparatus, systems, and methods are disclosed.

### CROSS REFERENCE TO RELATED APPLICATION(S)

The present application claims the priority benefit of U.S. Provisional Patent Application Ser. No. 61/476,561 filed Apr. 18, 2011 and entitled “A Network-Coding-Based Distributed File System,” which is incorporated herein by reference in its entirety.

### BACKGROUND INFORMATION

With the increasing growth of data to be managed, distributed storage systems provide a reliable platform for storing massive amounts of data over a set of storage nodes that are distributed over a network. For example, a real-life business model of distributed storage may be cloud storage, which enables enterprises and individuals to outsource their data backups to third-party repositories in the Internet.

### BRIEF DESCRIPTION OF THE DRAWINGS

FIG. 1 shows a layout of a file system with different implementations of the MDS codes wherein n=4 according to various embodiments.

FIG. 2 shows an architectural overview of a Network-Coding-Based Distributed File System (NCFS) according to various embodiments.

FIG. 3 shows topologies used in experiments according to various embodiments.

FIG. 4 shows normal upload/download throughputs of a first experiment (Experiment 1) according to various embodiments.

FIG. 5 shows degraded download throughputs of a second experiment (Experiment 2) according to various embodiments.

FIG. 6 shows repair throughputs of a third experiment (Experiment 3) according to various embodiments.

FIG. 7 shows a Network-Coding-Based Distributed File System (NCFS) according to various embodiments.

FIG. 8 shows a flowchart that illustrates a computer-implemented method of regenerating codes in a distributed file system according to various embodiments.

FIG. 9 shows a block diagram of an article of manufacture, including a specific machine, according to various embodiments.

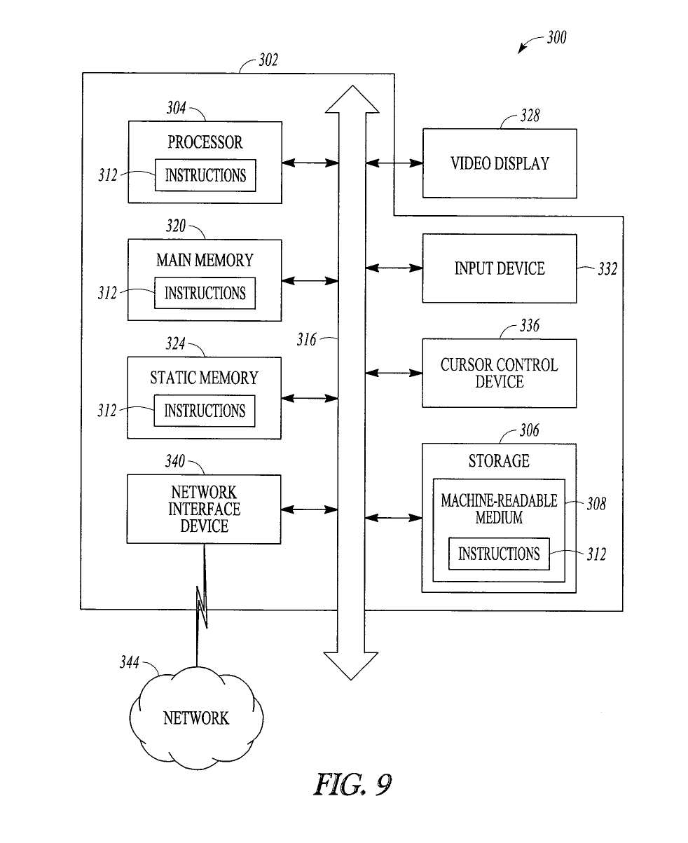

### DETAILED DESCRIPTION

With the increasing growth of data to be managed, distributed storage systems provide a reliable platform for storing massive amounts of data over a set of storage nodes that are distributed over a network. A real-life business model of distributed storage may include cloud storage (e.g., the Amazon Simple Storage Service (S3) storage for the Internet, and the Windows Azure™ cloud platform), which enables enterprises and individuals to outsource their data backups to third-party repositories in the Internet.

One feature of distributed storage is data reliability, which generally refers to the redundancy of data storage. Specifically, given a pre-determined level of redundancy, the distributed storage system should sustain normal input/output (I/O) operations with a defined tolerable number of node failures. In addition, in order to maintain the required redundancy, the storage system should support data repair, which involves reading data from existing nodes and reconstructing essential data in the new nodes. The repair process should be timely, so as to minimize the probability of data unreliability, given that more nodes can fail before the data repair process is completed.

Chapter 1: Introduction

An emerging application of network coding is to improve the robustness of distributed storage. In some cases, a class of regenerating codes, which are based on the concept of network coding, can be used to improve the data repair performance when some storage nodes are failed, as compared to traditional storage schemes such as erasure coding. However, deploying regenerating codes in practice, using know methods, may be infeasible.

Presented herein is the design and implementation of a Network-Coding-Based Distributed File System (NCFS), a proof-of-concept distributed file system that realizes regenerating codes under real network settings. An NCFS is a proxy-based file system that transparently stripes data across storage nodes. It adopts a layering design that allows extensibility, so as to provide a platform for exploring implementations of different storage schemes. Based on the NCFS, an empirical study of the traditional erasure codes RAID-5 and RAID-6, and a special regenerating code that is based on E-MBR, in different real network environments, is conducted.

Some studies propose a class of fast data repair schemes based on network coding for distributed storage systems. Such network-coding-based schemes, sometimes called regenerating codes, seek to intelligently mix and combine data blocks in existing nodes, and regenerate data blocks at new nodes.

However, the practicality of designing and implementing regenerating codes in distributed storage under realistic network settings is unknown. For example, many existing studies focus on theoretical analysis. They assume that storage nodes are intelligent, in the sense that nodes can inter-communicate and collaboratively conduct data repair, and may additionally require the support of encoding/decoding functions in some regenerating codes. Such intelligence assumptions require that storage nodes be programmable, and hence will limit the deployable platforms for practical storage systems.

In this disclosure, the design, implementation, and empirical experimentation of NCFS, a proof-of-concept prototype of a network-coding-based distributed file system, is presented. NCFS is a proxy-based file system that interconnects multiple storage nodes. It relays regular read/write operations between user applications and storage nodes. It also relays data among storage nodes during the data repair process, so that storage nodes do not need the intelligence to coordinate among themselves for data repair. NCFS can be built on Filesystem in Userspace (FUSE), a programmable user-space file system that provides interfaces for file system operations. From the point of view of user applications, NCFS presents a file system layer that transparently stripes data across physical storage nodes.

NCFS supports a specific regenerating coding scheme called the Exact Minimum Bandwidth Regenerating (E-MBR) codes, which seeks to minimize repair bandwidth. Some embodiments adapt E-MBR, which is proposed from a theoretical perspective, to provide a practical implementation. NCFS also supports RAID-based erasure coding schemes, so as to enable a comprehensive empirical study of different classes of data repair schemes for distributed storage under real network settings. NCFS realizes regenerating codes in a practical distributed file system.

Several embodiments are summarized as follows:
NCFS, a proxy-based file system, supports general read/write operations in a distributed storage setting, while enabling data repair during node failures.
NCFS adopts a layering design that enables extensibility. Some embodiments can implement different storage schemes without changing the file system logic. Also, some embodiments can have NCFS connect to different types of storage nodes without affecting the file system design and storage schemes.
Using NCFS, some embodiments compare the performance of read, write, and repair operations of RAID-5, RAID-6, and E-MBR within a local area network setting. Note that the empirical performance of a storage code depends on different factors, such as data transmissions, I/O accesses, encoding/decoding operations. Thus, some embodiments operate to understand the overall practical performance of a storage code, so as to complement the existing theoretical studies that focus on data transmissions only.

1.1. Definitions

Consider the design of a distributed file system, which can be realized as an array of n disks (or storage nodes). In this disclosure, the terms “disks” and “nodes” can be used interchangeably. The file system organizes data into blocks, each of which is of substantially fixed size. A stream of blocks, also called native blocks, is to be written to the file system. The stream may be divided into block groups, each with in native blocks. The native blocks in each block group are encoded to create c code blocks. The collection of m native blocks and c code blocks that correspond to a block group is called a segment, and the entire file system comprises a collection of segments.

In some embodiments, the storage schemes are based on a class of maximum distance separable (MDS) codes. For example, an MDS code is may be defined by the parameters n and k, such that any k (<n) out of n disks can be used to reconstruct the original native blocks. Given an MDS (n, k) code, the repair degree d is introduced for data repair, such that the repair for the lost blocks of one failed disk is achieved by connecting to d disks and regenerating the lost blocks in the new disk.

1.2. MDS Codes in NCFS

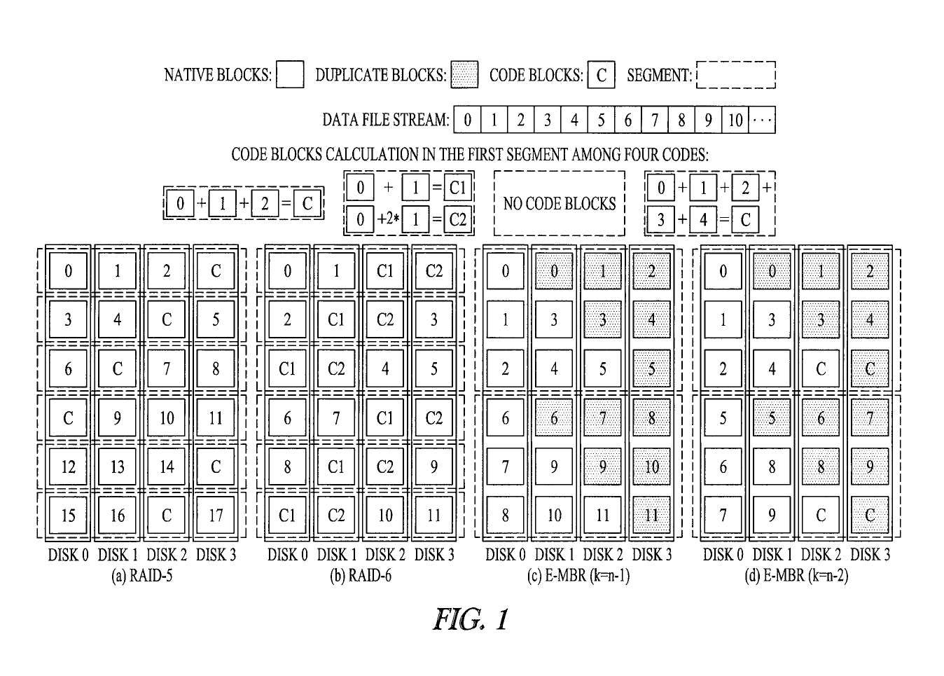

In NCFS, the following MDS codes, among others, are considered: RAID-5 (see e.g., D. A. Patterson, G. Gibson, and R. H. Katz. A case for redundant arrays of inexpensive disks (raid). In Proc. of ACM SIGMOD, 1988) and RAID-6 (see e.g., Intel. Intelligent RAID6 Theory Overview and Implementation, 2005), and exact minimum bandwidth regenerating (E-MBR) codes (see e.g., K. V. Rashmi, N. B. Shah, P. V. Kumar, and K. Ramchandran. Explicit construction of optimal exact regenerating codes for distributed storage. In Proc. of Allerton Conference, 2009). Both RAID-5 and RAID-6 are erasure codes in distributed file systems, while E-MBR uses the concept of network coding to minimize the repair bandwidth. The relationships of the parameters (i.e., n, k, d, m, c) for each of the MDS codes are summarized in FIG. 1, which also illustrates the layout of a file system with different implementations of the MDS codes for a special case n=4.

RAID-5. In RAID-5, the corresponding parameters are k=d=m=n−1, and c=1. RAID-5 can tolerate at most a single disk failure. In each segment, the single code block (or parity) is generated by the bitwise XOR-summing of the m=n−1 native blocks. To recover a failed disk, each lost block can be repaired from the blocks of the same segment in other surviving disks via the bitwise XOR-summing.

RAID-6. In RAID-6, the corresponding parameters are k=d=m=n−2, and c=2. RAID-6 can tolerate at most two disk failures with two code blocks known as the P and Q parities. The P parity is generated by the bitwise XOR-summing of the m=n−2 native blocks similar to RAID-5, while the Q parity is generated based on Reed-Solomon coding [10]. Similar to RAID 5, if one or two disks are failed, then each lost block can be repaired from the blocks of the same segment in other surviving disks.

E-MBR. The focus is on a case where d=n−1, and all feasible values of n, k, and d are considered. In the case of d=n−1, E-MBR can tolerate at most n−k disk failures. The number of native blocks in each segment is m=k(2n−k−1)/2. In some embodiments, for each native block, a duplicate copy is created, so the number of duplicate blocks in each segment is also in. By encoding the native blocks of a segment, c=(n−k)(n−k−1)/2 code blocks are formed. Duplicated copies of these c code blocks can be made. Thus, each segment corresponds to 2(m+c) blocks, including the native and code blocks and their duplicate copies.

In order to compare E-MBR with RAID-5 and RAID-6 under the same level of fault tolerance, two values of the parameter k may be selected in the disclosed implementation of the E-MBR code: (i) k=n−1 and (ii) k=n−2, while it is pointed out that E-MBR can be generalized to other feasible values of k. Note that for k=n−1, it is required to have c=0, so there is no code block. On the other hand, for k=n−2, it is required to have c=1 code block, which is generated as in RAID-5, i.e., by the bitwise XOR-summing of all native blocks in the segment.

Now the block allocation mechanism of E-MBR for k=n−1 or k=n−2 is explained. It is needed to consider a segment of m native blocks M₀, M₁, . . . Mₘ₋₁ and c code blocks C₀, C₁, . . . C_{c-1}, and their duplicate copies M̅₀, M̅₁, . . . M̅ₘ₋₁ and C̅₀, C̅₁, . . . C̅_{c-1}, respectively. Thus, the total number of blocks in one segment is 2(m+c)=n(n−1), implying that each storage node stores (n−1) blocks for each segment. To store a segment of blocks over n disks, NCFS first allocates a segment size of free space, represented as (n−1)×n block entries, where each row corresponds to the block offset within a segment of a disk, and each column corresponds to a disk. For each block Bᵢ (either a native or code block), a search is made for a free entry from top to bottom in a column-by-column manner, starting from the leftmost column. For its duplicate copy B̅ᵢ, a search is made for a free entry from left to right in a row-by-row manner starting from the topmost row. The allocation for each Bᵢ starts with the native blocks, followed by the code blocks. To illustrate the block allocation mechanism, FIG. 1(c) and FIG. 1(d) show the examples of (n=4, k=3, m=6, c=0) and (n=4, k=2, m=5, c=1), respectively.

To repair lost blocks during a single-node failure (for n=k−1 or n=k−2), it is noted that each native/code block has a duplicate copy and both copies are stored in two different disks. Thus, for each lost block, its duplicate copy is retrieved from another survival disk and is written to a new disk. It is noted that based on the block allocation mechanism, each survival disk contributes exactly one block for each segment.

To repair lost blocks during a two-node failure (for n=k-2), two cases are considered. If the duplicate copy of a lost block resides in a surviving disk, it is directly used for repair; if both the lost block and its duplicate copy are in the two failed disks, then the same approach is used as in RAID-5, i.e., the lost block is repaired by the bitwise XOR-summing of other native/code blocks of the same segment residing in other surviving disks.

Theoretical results. In general. E-MBR trades off a higher storage cost for a smaller repair bandwidth as compared to the traditional RAID schemes. To better understand this statement, suppose that M native blocks have been stored in the file system. Table 1 shows theoretical results of RAID- and E-MBR codes, with M original native blocks being stored. For example, Table 1 presents the total storage cost (i.e., the total number of blocks stored) and the amount of repair traffic in a single-node failure (i.e., total number of blocks retrieved from other d=n−1 surviving nodes) for the above MDS codes. For n=k−1, E-MBR incurs less repair traffic than RAID-5, but has higher storage cost. Similar observations are made between E-MBR and RAID-6 for n=k−2.

TABLE 1

| | Total storage cost | Repair traffic in single-node failure |
|---|---|---|
| RAID-5 | M/(1 − 1/n) | M |
| RAID-6 | M/(1 − 2/n) | M |
| E-MBR | 2*2M | 2*2M/n |
| k = n − 1 | | |
| E-MBR k = n − 2 | $2 * \frac{2 Mn ( n - 1 )}{( n - 2 ) ( n + 1 )}$ | $2 * \frac{2 M ( n - 1 )}{( n - 2 ) ( n + 1 )}$ |

1.3. Regenerating Codes

Regenerating codes are a class of storage schemes based on network coding for distributed storage systems. With regenerating codes, when one storage node is failed, data can be repaired at a new storage node by downloading data from surviving storage nodes. There exists a tradeoff spectrum between repair bandwidth and storage cost in regenerating codes. Minimum storage regenerating (MSR) codes occupy one end of the spectrum that corresponds to the minimum storage, and minimum bandwidth regenerating (MBR) codes occupy another end of the spectrum that corresponds to the minimum repair bandwidth.

Among others, three data repair approaches are considered: (i) exact repair, which regenerates the exact copies of the lost blocks of the failed node in the new node, (ii) functional repair, which may regenerate different copies from the lost blocks so long as the MDS property is maintained, and (iii) a hybrid of both. In general, with functional repair, some native blocks may no longer be kept after repair, so it is needed to access all blocks in a segment to decode a native block. This may not be desirable for general file systems as the read accesses will be slowed down.

To achieve fast read/write operations in a file system, maintaining the code in systematic form (i.e., a copy of each native block is kept in storage) might be considered. Thus, exact repair has received attention in literature, including the exact MSR (E-MSR) code and the exact MBR (E-MBR) code. There is another repair model called exact repair of the systematic part, which is a hybrid of exact repair and functional repair while keeping the storage in systematic part. On the other hand, among all the above codes, only E-MBR (with the repair degree d=n−1) does not require storage nodes be programmable to support encoding/decoding operations. As a starting point, E-MBR is therefore adopted as a building block in some NCFS prototype embodiments.

Chapter 2: Design and Implementation of NCFS Embodiments

2.1. Architectural Overview

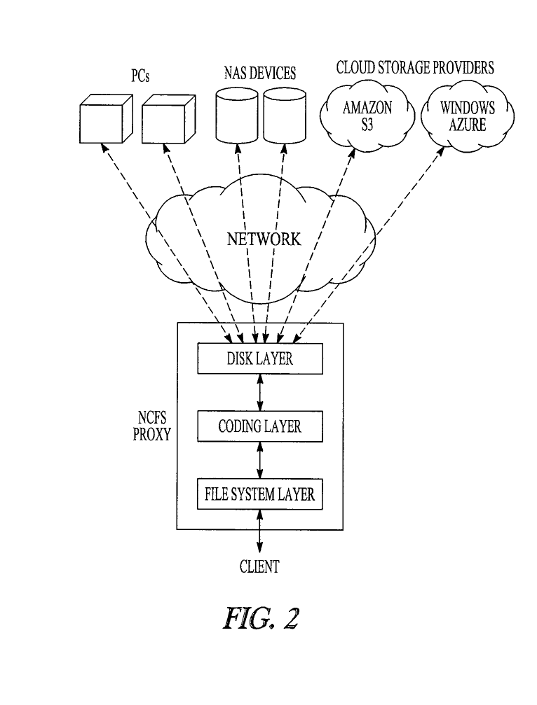

NCFS is designed as a proxy-based distributed file system that interconnects multiple storage nodes. FIG. 2 shows the architecture of NCFS. In some embodiments, the NCFS implementation does not require storage nodes be programmable to support encoding/decoding functions. Thus, the connected storage nodes can be of various types, so long as each storage node provides the standard interface for reading and writing data. For instance, a storage node could be a regular PC, network-attached storage (NAS) device, or even the repository of a cloud storage provider (e.g., Amazon S3 storage or Windows Azure™ cloud platform). The proxy design transparently stripes data across different storage nodes, without requiring the storage nodes to coordinate among themselves during the repair process as assumed in existing theoretical studies. Thus, NCFS can be made compatible with most today's storage frameworks.

As shown in FIG. 2, NCFS connects to storage nodes over the network (e.g., a local area network or the Internet), while it is assumed that NCFS is deployed locally as a file system on the client machine. Thus, in some embodiments, one goal is to improve the performance of read/write operations between NCFS and the storage nodes.

2.2. Layering Design of NCFS

NCFS adopts a layering design, as shown in FIG. 2. A feature of the layering design is that it enables extensibility, by which each layer can be extended for other functionalities without substantially affecting the entire logic of NCFS. The layers will be introduced below, and how each layer accommodates extensibility will be explained.

File system layer. In some embodiments, the file system layer is responsible for general file system operations, such as handling the requests of read, write and delete made by users. The file system may organize data intofixed-size blocks. Thus, each read/write/delete request may specify a data block to be accessed on the storage nodes (see the disk layer below). The file system may be enhanced to support the data repair operation. That is, if a node is failed, then the repair operation may (i) read data from survival nodes, (ii) regenerate lost data blocks, and (iii) write the regenerated blocks to a new node. The file system layer may be built on FUSE, a user-space framework that provides interfaces of file system operations for non-privileged developers to design new file systems. As compared to kernel-space file systems, FUSE may trade performance for extensibility.

Coding layer. The coding layer is responsible for the encoding/decoding functions of fault-tolerant storage schemes based on MDS codes. In some embodiments, in the implementation of NCFS, traditional erasure codes RAID 5 and RAID 6, and regenerating codes E-MBR (k=n−1) and E-MBR(k=n−2) (assuming d=n−1) may be implemented. With the above codes, the NCFS prototype does not require programmability of storage nodes. On the other hand, if this assumption can be relaxed and storage nodes are programmable (e.g., all storage nodes are regular PCs), then the coding layer can be extended to support other erasure/regenerating codes if necessary. For example, a class of MSR codes in the coding layer as well as the storage nodes can be implemented, so that the tradeoffs between the storage cost and repair bandwidth can be explored. Other layers remain unaffected with such extensions.

Disk layer. The disk layer provides a common interface for the file system to access different types of storage nodes. Since the file system organizes data into fixed-size blocks, each block can be uniquely identified by the mapping (node, offset), where node identifies a particular storage node, while offset specifies the location of the block within the storage node. The disk layer can then access a data block using the mapping provided by the file system, while the access method is transparent to the file system. For example, the disk layer can access regular PCs or NAS devices over the Ethernet and IP networks via protocols like ATA over Ethernet or the Internet Small Computer System Interface (iSCSI), respectively. The disk layer can also access the repositories of different cloud storage providers based on their own semantics.

2.3. Extensions

The NCFS prototype supports the basic file system semantics based on FUSE. However, different extensions atop the existing design of NCFS can be made to improve performance.

In NCFS, each read/write request directly accesses storage nodes. One extension is to include a cache layer, which caches recently accessed blocks in main memory. If the read/write requests preserve data locality, then they can directly access the blocks via memory without accessing the storage nodes. The cache layer can reside between the coding layer and the disk layer (see FIG. 2), and it is transparent to the file system layer.

NCFS may be deployed as a single proxy, which may be vulnerable to a single point of failure. An extension is to use multiple proxies to improve the robustness of NCFS.

Chapter 3: Experiments

Using an NCFS prototype, the empirical performance of different storage schemes, including the traditional erasure codes (i.e., RAID-5 and RAID-6) and regenerating codes (i.e., E-MBR (k=n−1) and E-MBR (k=n−2)) are compared. The overall empirical performance depends on different factors, such as data transmissions over the network, I/O accesses within storage nodes, and block encoding/decoding operations within NCFS.

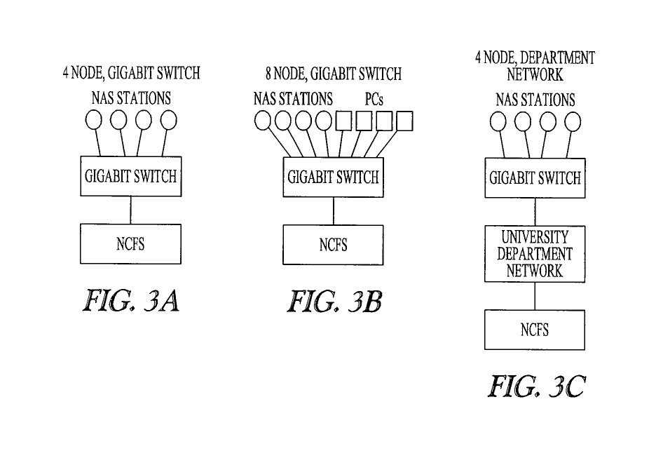

Topologies. NCFS has been deployed on an Intel Quad-Core 2.66 GHz machine with 4 GB RAM and experiments have been conducted based on three local area network topologies as shown in FIG. 3.

FIG. 3(a) shows the basic setup, in which NCFS is interconnected via a Gigabit switch with four network-attached storage (NAS) stations (i.e., n=4). FIG. 3(b) considers a larger-scale setup and studies the scalability of NCFS. NCFS is interconnected with eight storage nodes (i.e., n=8), including the four NAS stations and four regular PCs, via a Gigabit switch. FIG. 3(c) considers a relatively more bandwidth-limited network setting, in which NCFS is interconnected with the four NAS stations (i.e., n=4) over a university department network. In all topologies, NCFS communicates with the storage nodes via the ATA over Ethernet protocol.

Metrics. The throughput (in MB/s) of different operations is considered: (i) normal upload/download operations with no failure, (ii) degraded download operations with node failures, and (iii) repair operations during node failures. Each throughput measurement is obtained over the average of five runs.

Experiment 1 (Normal upload/download operations). Suppose that there is no node failure. This experiment studies the throughput of the normal upload/download operations. Here, a file of size 256 MB to/from the storage nodes is uploaded/download. When a 256-MB file is uploaded, different storage schemes have different actual storage sizes based on how they introduce redundancy (see Table I). For instance, when n=4, the actual storage sizes of different codes are: 341 MB for RAID-5, 512MB for RAID-6, 512 MB for E-MBR (k=3), and 614 MB for E-MBR (k=2).

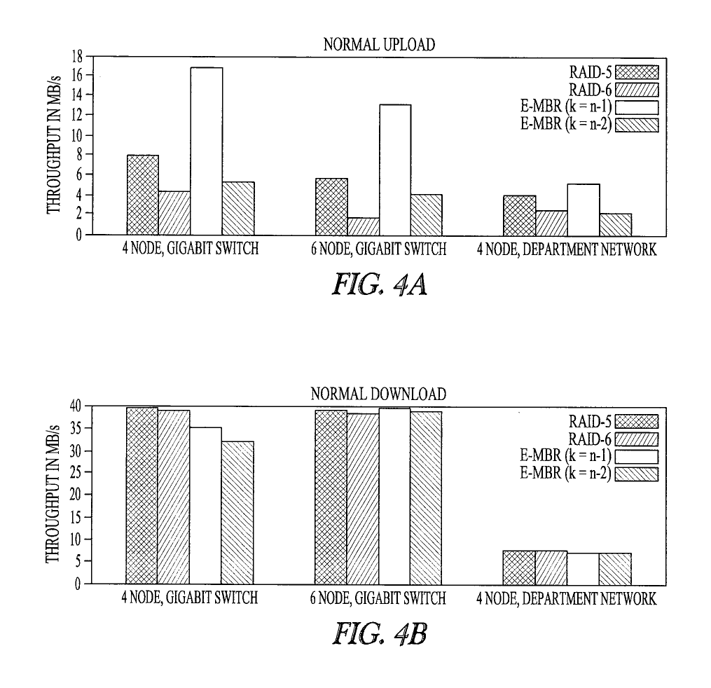

FIG. 4 shows throughput of normal upload/download operations in Experiment 1. FIG. 4(a) shows the upload throughput. E-MBR (k=n−1) has the largest throughout among all codes, since it does not need to access any code blocks. For other codes, when NCFS is about to upload a native block, it needs to read and update the corresponding code block(s) of the same segment on the storage nodes, and this introduces additional read accesses. RAID-5 has the second largest upload throughput as it transmits fewer blocks than RAID-6 and E-MBR (k=n−2). E-MBR (k=n−2) outperforms RAID-6 in both 4-node and 8-node Gigabit-switch settings, but the difference becomes small in the department network setting. The reason is that RAID-6 uses Reed-Solomon coding to compute the Q-parity code blocks, so the computation overhead dominates the transmission overhead when the topology has high network capacity (e.g., a Gigabit-switch setting), but becomes less significant over the more bandwidth-limited setting (e.g., a department network). The upload throughput is smaller in the 8-node Gigabit-switch setting than in the 4-node one. This may be related to disk locality of I/O accesses.

FIG. 4(b) shows the download throughput. In each topology, all storage schemes have similar download throughput. Download operations generally have higher throughput than upload operations, mainly because NCFS can only download one copy of each native block without the need of accessing other code blocks, or duplicate blocks (in E-MBR).

Experiment 2 (Degraded download operations). The performance of download operations when some storage nodes are failed is considered. In the experiment, a 256 MB file is first uploaded to all storage nodes. Then one/two nodes are picked to disable, and then evaluate the throughput of downloading the 256 MB file. Here, the leftmost nodes in the array (see FIG. 1) are picked to disable, while the observations are similar if other nodes are disabled.

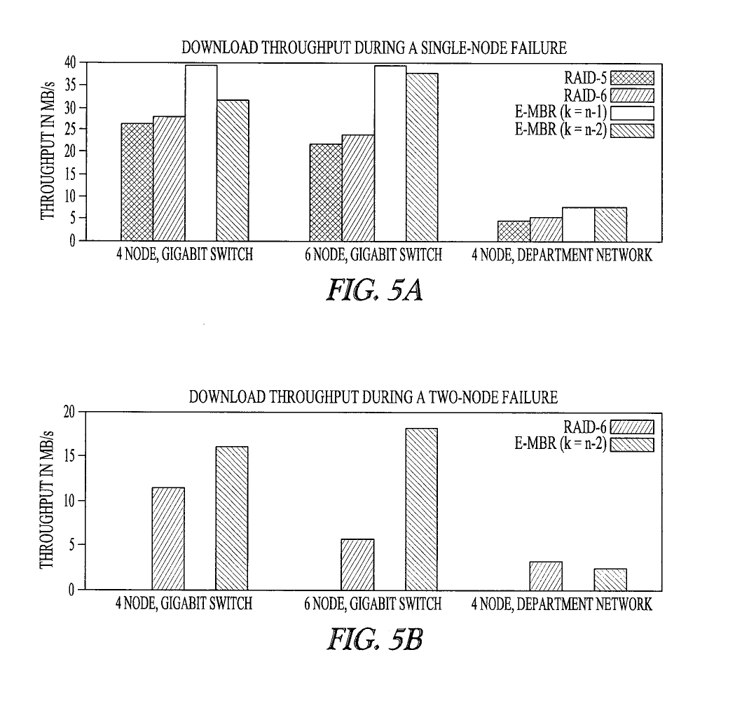

FIG. 5 shows degraded download throughputs of Experiment 2 according to various embodiments. FIG. 5(a) shows the download throughput during a single-node failure. It is observed that the E-MBR codes have higher download throughput than RAID codes. The reason is that for each lost native block, there must be a corresponding duplicate copy (see FIG. 1), which could be used for download. On the other hand, RAID codes need to additionally access the corresponding code block of the same segment to recover each lost native block.

FIG. 5(b) shows the download throughput during a two-node failure (for RAID-6 and E-MBR (k=n−2) only). E-MBR (k=n−2) outperforms RAID-6 in the Gigabit-switch settings, mainly because RAID-6 uses Reed-Solomon coding to recover lost native blocks and incurs higher computation overhead than E-MBR. Using the same reasoning as in Experiment 1, E-MBR (k=n−2) has higher throughput than RAID-6 in well-connected settings.

Experiment 3 (Repair operations). In some embodiments, the repair operation of a failed node includes three steps: (i) transmission of the existing blocks from survival nodes to NCFS, (ii) regeneration for lost blocks of the failed node in NCFS, and (iii) transmission of the regenerated blocks from NCFS to a new node. If there is more than one failed node, then the repair operation may be applied for each failed node one-by-one. In this experiment, the performance of the repair operation (i.e., from step (i) to step (iii)) is evaluated. For the single-node failure case, the throughput of repairing the failed node is considered. For the two-node failure case, only the throughput of repairing the first failed node is considered, since after the first failed node is repaired, repairing the second failed node is reduced to the single-node failure case.

In some embodiments, each segment contains both original native blocks as well as redundant blocks (e.g., code blocks, or duplicate blocks). For fair comparison, the effective throughput of repair, which is defined as follows, is considered. If each segment contains a fraction f (where 0<f<1) of redundant blocks and the time to repair a total of N-MB all lost blocks (including both original native blocks and redundant blocks) of a failed node is Ts, then the effective throughput of repair is defined as (1−f)N/T (in MB/s).

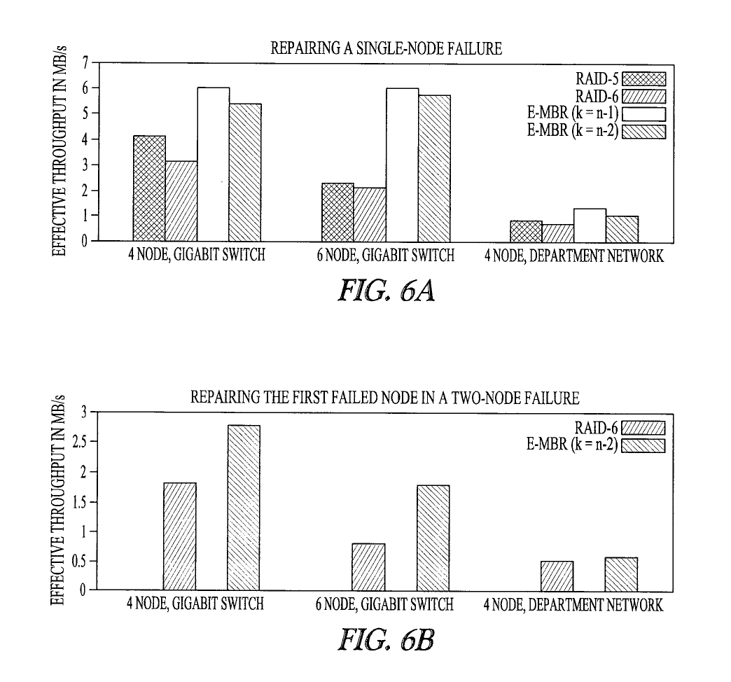

FIG. 6 shows repair throughput of Experiment 3 according to various embodiments. FIG. 6(a) shows the repair throughput of a single-node failure. It is observed that in the Gigabit-switch settings, E-MBR codes achieve significantly higher repair throughput than RAID codes. For example, the repair throughput of E-MBR (k=n−1) is 1.91× and 2.61× over that of RAID-5 in 4-node and 8-node Gigabit switch settings, respectively. The main reason is that E-MBR codes retrieve fewer blocks than RAID codes for repair.

On the other hand, in the department network setting, all storage nodes have similar effective throughput. The reason is that the performance bottleneck now lies on the transmission of regenerated blocks from NCFS to the new node. Since E-MBR stores more redundant blocks than RAID codes in each storage node, it needs more time to transmit blocks from NCFS to the new node, and this overhead reduces the effective throughput of E-MBR.

FIG. 6(b) shows the repair throughput for the first failed node during a two-node failure (for RAID-6 and E-MBR (k=n−2) only). Similar observations are made as in the two-node failure degrade download case (See FIG. 5(b)).

Summary. The empirical performance of different storage schemes in different network settings has been compared. In repair, E-MBR significantly outperforms RAID codes in the Gigabit-switch settings, mainly because it downloads fewer blocks and has lower coding complexity. On the other hand, mitigating the transmission bottleneck between NCFS and the new storage nodes, which can degrade the repair throughput as shown in the department-network setting, might be considered. E-MBR seeks to minimize repair bandwidth with a tradeoff of higher storage overhead.

In some embodiments, it may be possible to use other classes of regenerating codes, such as MSR codes that seek to minimize storage overhead, with the relaxed assumption that storage nodes are programmable to support encoding/decoding functions.

Chapter 4: Machine-Readable Media, Apparatus, Systems, and Methods

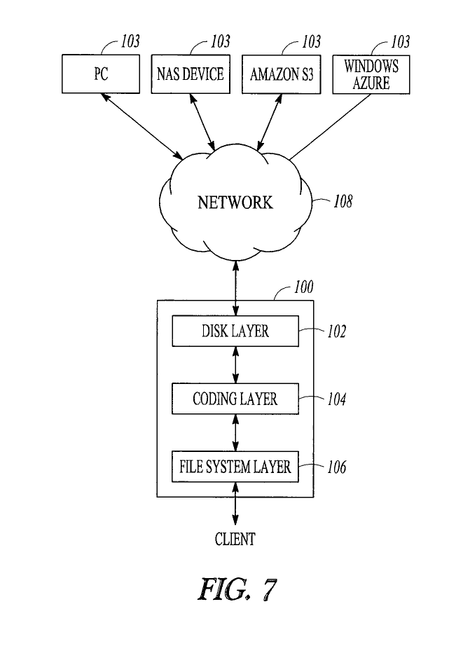

A NCFS file system 100, as shown in FIG. 7, may include a disk layer 102, a coding layer 104, and a file system layer 106, and may communicate with a variety of storage nodes 103 (e.g., a PC, a Network-Attached Storage (NAS) device, Amazon S3 storage, or a Windows Azure™ cloud platform) over one or more networks 108. For example, the file system layer 106 may be configured to receive a request for an operation on data within a data block. The request specifies the data block to be accessed in a storage node of a plurality of storage nodes 103. The storage node 103 may form a part of the file system 100. The disk layer 102 may provide an interface to the NCFS system 100 to provide access the plurality of storage nodes 103 via the network 108. The coding layer 104 may be connected between the file system layer 106 and the disk layer 102 to encode and/or decode functions of fault-tolerant storage schemes based on a class of maximum distance separable (MDS) codes.

The networks 108 may be wired, wireless, or a combination of wired and wireless. Also, at least one of the networks 108 may be a satellite-based communication link, such as the WINDS (Wideband Inter-Networking engineering test and Demonstration Satellite) communication link or any other commercial satellite communication links. The system 100 and apparatus (or layers) 102, 104, 106 can be used to implement, among other things, the processing associated with the methods 200 of FIG. 2. Modules may comprise hardware, software, and firmware, or any combination of these. Additional embodiments may be realized.

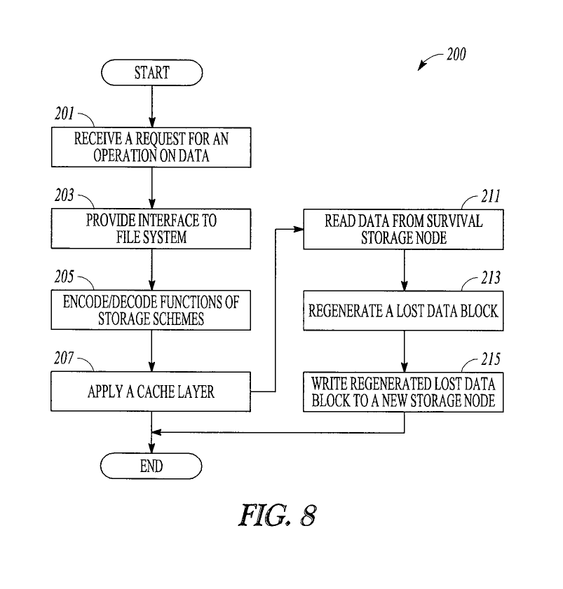

FIG. 8 shows a computer-implemented method 200 of regenerating codes in a distributed file system 100. The method 200 may include receiving 201, at a file system layer 106, a request for an operation on data within a data block. The request may specify the data block to be accessed within a storage node of a plurality of storage nodes 103. The method 200 may also include providing 203 an interface to the file system 106 to access the plurality of storage nodes 103 via a network 108, using a disk layer 102. The method 200 may also include encoding and decoding 205 functions of fault-tolerant storage schemes based on a class of maximum distance separable (MDS) codes, using a coding layer 104 communicatively coupled between the file system layer 106 and the disk layer 102.

The NCFS system 100 in FIG. I may be implemented in a machine-accessible and readable medium that is operational over one or more networks 108. For example, FIG. 3 is a block diagram of an article 300 of manufacture, including a specific machine 302, according to various embodiments of the invention. Upon reading and comprehending the content of this disclosure, one of ordinary skill in the art will understand the manner in which a software program can be launched from a computer-readable medium in a computer-based system to execute the functions defined in the software program.

One of ordinary skill in the art will further understand the various programming languages that may be employed to create one or more software programs designed to implement and perform the methods disclosed herein. The programs may be structured in an object-oriented format using an object-oriented language such as Java or C#. In some embodiments, the programs can be structured in a procedure-oriented format using a procedural language, such as assembly or C. The software components may communicate using any of a number of mechanisms well known to those of ordinary skill in the art, such as application program interfaces or intercommunication techniques, including remote procedure calls. The teachings of various embodiments are not limited to any particular programming language or environment. Thus, other embodiments may be realized.

For example, an article 300 of manufacture, such as a computer, a memory system, a magnetic or optical disk, some other storage device, and/or any type of electronic device or system may include one or more processors 304 coupled to a machine-readable medium 308 such as a memory (e.g., removable storage media, as well as any tangible memory device including an electrical, optical, or electromagnetic conductor) having instructions 312 stored thereon (e.g., computer program instructions), which when executed by the one or more processors 304 result in the machine 302 performing any of the actions described with respect to the methods above.

The machine 302 may take the form of a specific computer system having a processor 304 coupled to a number of components directly, and/or using a bus 316. Thus, the machine 302 may be similar to or identical to the apparatuses 202, 204, 206 or system 200 shown in FIG. 2.

Turning now to FIG. 3, it can be seen that the components of the machine 302 may include main memory 320, static or non-volatile memory 324, and mass storage 306. Other components coupled to the processor 304 may include an input device 332, such as a keyboard, or a cursor control device 336, such as a mouse. An output device 328, such as a video display, may be located apart from the machine 302 (as shown), or made as an integral part of the machine 302.

A network interface device 340 to couple the processor 304 and other components to a network 344 may also be coupled to the bus 316. The instructions 312 may be transmitted or received over the network 344 via the network interface device 340 utilizing any one of a number of well-known transfer protocols (e.g., Hyper Text Transfer Protocol and/or Transmission Control Protocol). Any of these elements coupled to the bus 316 may be absent, present singly, or present in plural numbers, depending on the specific embodiment to be realized.

The processor 304, the memories 320, 324, and the storage device 306 may each include instructions 312 which, when executed, cause the machine 302 to perform any one or more of the methods described herein. In some embodiments, the machine 302 operates as a standalone device or may be connected (e.g., networked) to other machines. In a networked environment, the machine 302 may operate in the capacity of a server or a client machine in server-client network environment, or as a peer machine in a peer-to-peer (or distributed) network environment.

The machine 302 may comprise a personal computer (PC), a tablet PC, a set-top box (STB), a PDA, a cellular telephone, a web appliance, a network router, switch or bridge, server, client, or any specific machine capable of executing a set of instructions (sequential or otherwise) that direct actions to be taken by that machine to implement the methods and functions described herein. Further, while only a single machine 302 is illustrated, the term “machine” shall also be taken to include any collection of machines that individually or jointly execute a set (or multiple sets) of instructions to perform any one or more of the methodologies discussed herein.

While the machine-readable medium 308 is shown as a single medium, the term “machine-readable medium” should be taken to include a single medium or multiple media (e.g., a centralized or distributed database, and/or associated caches and servers, and or a variety of storage media, such as the registers of the processor 304, memories 320, 324, and the storage device 306 that store the one or more sets of instructions 312). The term “machine-readable medium” shall also be taken to include any medium that is capable of storing, encoding or carrying a set of instructions for execution by the machine and that cause the machine 302 to perform any one or more of the methodologies of the present invention, or that is capable of storing, encoding or carrying data structures utilized by or associated with such a set of instructions. The terms “machine-readable medium” or “computer-readable medium” shall accordingly be taken to include tangible media, such as solid-state memories and optical and magnetic media.

Various embodiments may be implemented as a stand-alone application (e.g., without any network capabilities), a client-server application or a peer-to-peer (or distributed) application. Embodiments may also, for example, be deployed by Software-as-a-Service (SaaS), an Application Service Provider (ASP), or utility computing providers, in addition to being sold or licensed via traditional channels. Thus, many embodiments can be realized.

For example, an NCFS may comprise a file system layer configured to receive a request for an operation on data within a data block; a disk layer to provide an interface to the file system to provide access the plurality of storage nodes via a network; and a coding layer connected between the file system layer and the disk layer. In some embodiments, the request specifying the data block to be accessed is in a storage node of a plurality of storage nodes, the storage node forming a part of the file system. In some embodiments, the coding layer encodes and/or decodes functions of fault-tolerant storage schemes based on a class of maximum distance separable (MDS) codes.

In some embodiments, the file system may further comprise a cache layer connected between the coding layer and the disk layer of the file system to cache a recently accessed block in a main memory of the file system.

In some embodiments, the file system is configured to organize data into fixed-size blocks in the storage node. In some embodiments, the block comprises one of the fixed-size blocks in the storage node, and the block is uniquely identified by a mapping. In some embodiments, the mapping includes a storage node identifier to identify the storage node and a location indicator to specify a location of the block within the storage node.

In some embodiments, the request comprises a request to read, write, or delete the data.

In some embodiments, the coding layer is configured to implement erasure codes included in one of a Redundant Array of Independent Disks (RAID) 5 standard or a RAID 6 standard.

In some embodiments, the coding layer is configured to implement regenerating codes. In some embodiments, the regenerating codes include Exact Minimum Bandwidth Regenerating (E-MBR) codes E-MBR(n, n−1. n−1) and E-MBR(n, n−2, n−1), wherein n is a total number of the plurality of storage nodes, wherein the E-MBR(n, n−1, n−1) code tolerates single-node failure, and wherein the E-MBR(n, n−2, n−1) tolerates two-node failure.

In some embodiments, a computer-implemented method of regenerating codes in a distributed file system comprises: receiving, at a file system layer, a request for an operation on data within a data block, the request specifying the data block to be accessed within a storage node of a plurality of storage nodes; providing an interface to the file system to access the plurality of storage nodes via a network, using a disk layer; and encoding and decoding functions of fault-tolerant storage schemes based on a class of maximum distance separable (MDS) codes, using a coding layer communicatively coupled between the file system layer and the disk layer.

In some embodiments, the method of regenerating codes in a distributed file system further comprises: performing a repair operation when the storage node fails.

In some embodiments, wherein the repair operation of the method comprises: reading data from a survival storage node; regenerating a lost data block to provide a regenerated version of the lost data block; and writing the regenerated version to a new storage node.

In some embodiments, the method of regenerating codes in a distributed file system further comprises caching a recently accessed block in a main memory of the file system, using a cache layer communicatively coupled between the coding layer and the disk layer.

In some embodiments, the method of regenerating codes in a distributed file system further comprises organizing a plurality of data, including the data, into fixed-size blocks in the storage node. In some embodiments, the method further comprises uniquely identifying the block by mapping. In some embodiments, the mapping comprises identifying the storage node with a storage node identifier, and specifying a location of the block within the storage node with a location indicator.

In some embodiments, a computer-readable, tangible storage device may store instructions that, when executed by a processor, cause the processor to perform a method. The method may comprise receiving, at a file system layer, a request for an operation on data within a data block, the request specifying the data block to be accessed within a storage node of a plurality of storage nodes; providing an interface to the file system to access the plurality of storage nodes via a network, using a disk layer; and encoding and decoding functions of fault-tolerant storage schemes based on a class of maximum distance separable (MDS) codes, using a coding layer communicatively coupled between the file system layer and the disk layer.

In some embodiments, the method may further comprise applying a cache layer between the coding layer and the disk layer of the file system to cache a recently accessed block in a main memory of the file system.

In some embodiments, the method may further comprise performing a repair operation when the storage node of the plurality of the storage nodes fails.

In some embodiments, the method may further comprise reading data from a survival storage node; regenerating a lost data block to provide a regenerated lost block; and writing the regenerated lost data block to a new storage node.

In some embodiments, a computer-implemented method of repairing a failed node may comprise identifying a failed storage node among a plurality of nodes; transmitting an existing block from a survival node among the plurality of nodes to a network-coding-based distributed file system (NCFS); regenerating a data block for a lost block of the failed storage node in the NCFS using an Exact Minimum Bandwidth Regenerating (E-MBR) based code, to provide a regenerated data block; and transmitting the regenerated data block from the NCFS to a new node.

Chapter 5: Conclusions

NCFS, a proxy-based distributed file system that can realize traditional erasure codes and network-coding-based regenerating codes in practice, has been presented. NCFS adopts a layering design that allows extensibility. NCFS can be used to evaluate and implement different storage schemes under real network settings, in terms of the throughput of upload, download, and repair operations. NCFS provides a practical and extensible platform for different researchers to explore the empirical performance of various storage nodes in a practical manner.

The Abstract of the Disclosure is provided to comply with 37 C.F.R. §1.72(b) requiring an abstract that will allow the reader to quickly ascertain the nature of the technical disclosure. It is submitted with the understanding that it will not be used to interpret or limit the scope or meaning of the claims. In the foregoing Detailed Description, various features are grouped together in a single embodiment for the purpose of streamlining the disclosure. This method of disclosure is not to be interpreted to require more features than are expressly recited in each claim. Rather, inventive subject matter may be found in less than all features of a single disclosed embodiment. Thus the following claims are hereby incorporated into the Detailed Description, with each claim standing on its own as a separate embodiment.

1. A network-coding-based distributed file system (NCFS), comprising:
a file system layer configured to receive a request for an operation on data within a data block, the request specifying the data block to be accessed in a storage node of a plurality of storage nodes, the storage node forming a part of the file system;
a disk layer to provide an interface to the file system to provide access the plurality of storage nodes via a network; and
a coding layer connected between the file system layer and the disk layer, the coding layer to encode and/or decode functions of fault-tolerant storage schemes based on a class of maximum distance separable (MDS) codes.

2. The file system of claim 1, further comprising a cache layer connected between the coding layer and the disk layer of the file system to cache a recently accessed block in a main memory of the file system.

3. The file system of claim 1, wherein the file system is configured to organize data into fixed-size blocks in the storage node.

4. The file system of claim 3, wherein the block comprises one of the fixed-size blocks in the storage node, and wherein the block is uniquely identified by a mapping.

5. The file system of claim 4, wherein the mapping includes a storage node identifier to identify the storage node and a location indicator to specify a location of the block within the storage node.

6. The file system of claim 1, wherein the request comprises a request to read, write, or delete the data.

7. The file system of claim 1, wherein the coding layer is configured to implement erasure codes included in one of a Redundant Array of Independent Disks (RAID) 5 standard, or a RAID 6 standard.

8. The file system of claim 1, wherein the coding layer is configured to implement regenerating codes.

9. The file system of claim 8, wherein the regenerating codes include Exact Minimum Bandwidth Regenerating (E-MBR) codes E-MBR(n, n−1, n−1) and E-MBR(n, n−2, n−1), wherein n is a total number of the plurality of storage nodes, wherein the E-MBR(n, n−1, n−1) code tolerates single-node failure, and wherein the E-MBR(n, n−2, n−1) tolerates two-node failure.

10. A computer-implemented method of regenerating codes in a distributed file system, comprising:
receiving, at a file system layer, a request for an operation on data within a data block, the request specifying the data block to be accessed within a storage node of a plurality of storage nodes;
providing an interface to the file system to access the plurality of storage nodes via a network, using a disk layer; and
encoding and decoding functions of fault-tolerant storage schemes based on a class of maximum distance separable (MDS) codes, using a coding layer communicatively coupled between the file system layer and the disk layer.

11. The method of claim 10, further comprising:
performing a repair operation when the storage node fails.

12. The method of claim 11, wherein the repair operation comprises:
reading data from a survival storage node;
regenerating a lost data block to provide a regenerated version of the lost data block; and
writing the regenerated version to a new storage node.

13. The method of claim 10, further comprising:
caching a recently accessed block in a main memory of the file system, using a cache layer communicatively coupled between the coding layer and the disk layer.

14. The method of claim 10, further comprising:
organizing a plurality of data, including the data block, into fixed-size blocks in the storage node.

15. The method of claim 10, further comprising:
uniquely identifying the data block by mapping.

16. The method of claim 15, wherein the mapping comprises:
identifying the storage node with a storage node identifier, and specifying a location of the data block within the storage node with a location indicator.

17. A computer-readable, tangible storage device storing instructions that, when executed by a processor, cause the processor to perform a method comprising:
receiving, at a file system layer, a request for an operation on data within a data block, the request specifying the data block to be accessed within a storage node of a plurality of storage nodes;
providing an interface to the file system to access the plurality of storage nodes via a network, using a disk layer; and
encoding and decoding functions of fault-tolerant storage schemes based on a class of maximum distance separable (MDS) codes, using a coding layer communicatively coupled between the file system layer and the disk layer.

18. The storage device of claim 17, wherein the method further comprises:
applying a cache layer between the coding layer and the disk layer of the file system to cache a recently accessed block in a main memory of the file system.

19. The storage device of claim 17, wherein the method further comprises:
performing a repair operation when the storage node of the plurality of the storage nodes fails.

20. The storage device of claim 19, wherein the method further comprises:
reading data from a survival storage node;
regenerating a lost data block to provide a regenerated lost block; and
writing the regenerated lost data block to a new storage node.

21. A computer-implemented method of repairing a failed node, comprising:
identifying a failed storage node among a plurality of nodes;
transmitting an existing block from a survival node among the plurality of nodes to a network-coding-based distributed file system (NCFS);
regenerating a data block for a lost block of the failed storage node in the NCFS using an Exact Minimum Bandwidth Regenerating (E-MBR) based code, to provide a regenerated data block; and
transmitting the regenerated data block from the NCFS to a new node.
